(19) United States
(12) Patent Application Publication
(10) Pub. No.: US 2011/0056659 A1
(43) Pub. Date: Mar. 10, 2011

(54) Heat Dissipating Module

(76) Inventors: Alex Horng, Kaohsiung (TW); Ching-Shen Hong, Kaohsiung (TW)

(21) Appl. No.: 12/554,958

(22) Filed: Sep. 7, 2009

(51) Int. Cl. F28D 15/04; F28F 7/00; H05K 7/20

(52) U.S. Cl. 165/104.26; 165/122; 165/185

(57) ABSTRACT

A heat dissipating module includes a housing having a bottom wall and a peripheral wall interconnected to a periphery of the bottom wall. The peripheral wall defines a compartment and includes an air inlet in communication with the compartment and an air outlet in communication with the compartment. A stator is received in the compartment of the housing. An impeller is coupled to the stator. A lid can be mounted to the air inlet side of the housing. A plurality of rows of fins is formed on at least one heat conducting section of at least one of the peripheral wall, the bottom wall, and the lid and is located in the compartment.

### BACKGROUND OF THE INVENTION

1. Field of the Invention

The present invention relates to a heat dissipating module and, more particularly, to a heat dissipating module that can be coupled to various heat sources at the same time.

2. Description of the Related Art

Nowadays, various heat sources are generated during operation of all kinds of electronic devices. To prevent the electronic devices from being damaged due to overheat, a heat dissipating module is mounted to a predetermined position of a heat source.

FIG. 1 shows a conventional heat dissipating module 7 including a heat sink 71, a plurality of heat pipes 72, and a fan 73. The heat sink 71 includes a plurality of fins 711. The heat pipes 72 are coupled to the fins 711 to enhance the heat conducting efficiency. The fan 73 is coupled to an end of the heat sink 71. The heat sink 71 is coupled to a heat source (such as a central processing unit, a main board, electronic chips, or a lighting module) of an electronic device. The heat generated by the heat source can be conducted to the heat sink 71 and the heat pipes 72. At the same time, the fan 73 guides air currents to proceed with heat dissipation of the heat sink 71, so that the electronic device can operate normally. An example of such a heat dissipating module is disclosed in Taiwan Utility Model No. M358217. However, the heat sink 71 coupled to a side of the fan 73 causes limitation to reduction of the volume and axial length of the heat dissipating module 7. Thus, problems exist when installing the heat dissipating module in a limited space surrounding the heat source. Furthermore, the heat dissipating module 71 can provide the desired heat dissipating effect only when the heat sink 71 is coupled to a predetermined location of the heat source. Namely, heat dissipating modules of the same type can only be utilized with a single heat source, not allowing use with various heat sources at the same time. Further, the heat sink 71 and the fan 73 must be assembled together before dissipating heat from the heat source of the electronic device. Further, the heat dissipating module 7 is complicated in structure due to having many components and, thus, does not allow compact designs for miniature electronic devices. Further, the air currents driven by the fan 73 are liable to undesirably disperse to the environment via two sides of the heat sink 71, providing limited heat dissipating effect while forming turbulence.

FIG. 2 shows another conventional heat dissipating module 8 including a box 81 defining a wind passageway 811. The box 81 further includes an air inlet 812 and an air outlet 813 both in communication with the wind passageway 811. An impeller 82 is received in the wind passageway 811 and aligned with the air inlet 812. Fins 83 are formed inside and outside of the box 81. The box 81 can be coupled to a heat source of an electronic device. Air currents can be driven by the impeller 82 into the box 81 and pass through the fins 83 inside of the box 81 and then exit via the air outlet 813, so that the heat generated by the heat source can be carried to the environment for heat dissipation purposes. Instead of using the heat sink 71, the heat dissipating module 8 includes fins 83 directly formed in predetermined locations of the box 81. An example of such a heat dissipating module is disclosed in Taiwan Utility Model No. M261013. However, the fins 83 outside of the box 81 limit reduction of the volume while having complicated structure, leading to inconvenient or even impossible installation of the heat dissipating module 8 when the space surrounding the heat source of the electronic device is limited. Further, the heat dissipating module 8 is not suitable for coupling various heat sources at the same time and can not easily be assembled. Further, the fins 83 inside of the box 81 of the heat dissipating module 8 are adjacent the air outlet 813, such that the air currents driven by the impeller 82 into the wind passageway 811 are liable to undesirably disperse to the environment via the fins 83 inside of the box 81, adversely affecting the heat dissipating effect.

FIG. 3 shows a further conventional heat dissipating module 9 including a fan 91, a filtering net 92, and an air guiding housing 93. The fan 91 is mounted in the air guiding housing 93 having an air inlet 931 and an air outlet 932. An inlet of the fan 91 is aligned with the air inlet 931, and an outlet of the fan 91 is aligned with the air outlet 932. Fins 94 are provided in the air outlet 932 of the air guiding housing 93. The air guiding housing 93 can be coupled to a heat source of an electronic device. Air currents are driven by the fan 91 to pass through the air inlet 931, the inlet and outlets of the fan 91, the fins 94, and the air outlet 932 to provide heat dissipating effect. Instead of using the heat sink 71, the heat dissipating module 9 includes fins 94 directly formed in the air guiding housing 93. Such a heat dissipating module is disclosed in Taiwan Utility Model No. M335723. However, the fan 91 mounted in the air guiding housing 93 limits reduction of the volume while having the disadvantages of complicated structure and inconvenient assembly. Furthermore, the heat dissipating module 9 is not suitable for coupling various heat sources at the same time, either. Further, the fins 94 formed inside of the air guiding housing 93 are adjacent the air outlet 932 and, thus have similar disadvantages of the heat dissipating module 8. As a result, the heat dissipating effect provided by the heat dissipating module 9 is unsatisfactory.

### SUMMARY OF THE INVENTION

An objective of the present invention is to provide a heat dissipating module that can be installed without the need of a large space.

Another objective of the present invention is to provide a heat dissipating module that can be coupled to various heat sources at the same time.

A further objective of the present invention is to provide a heat dissipating module with enhanced assembling convenience.

Still another objective of the present invention is to provide a heat dissipating module with less complicated structure.

Yet another objective of the present invention is to provide a heat dissipating module with enhanced heat dissipating effect.

In a first aspect, a heat dissipating module according to the preferred teachings of the present invention includes a housing having a bottom wall and a peripheral wall interconnected to a periphery of the bottom wall. The peripheral wall includes at least one heat conducting section and defines a compartment. The peripheral wall further includes an air inlet in communication with the compartment and an air outlet in communication with the compartment. A stator is received in the compartment of the housing. An impeller is coupled to the stator. A plurality of rows of fins is formed on the at least one heat conducting section of the peripheral wall and located in the compartment.

In a second aspect, a heat dissipating module according to the preferred teachings of the present invention includes a housing having a bottom wall and a peripheral wall interconnected to a periphery of the bottom wall. The peripheral wall defines a compartment and includes an air inlet in communication with the compartment and an air outlet in communication with the compartment. A stator is received in the compartment of the housing. An impeller is coupled to the stator. A lid is coupled to the air inlet side of the housing and includes an inlet aligned with the air inlet of the housing. The lid further includes at least one heat conducting section. A plurality of rows of fins is formed on the at least one heat conducting section of the lid and located in the compartment.

In a third aspect, a heat dissipating module according to the preferred teachings of the present invention includes a housing having a bottom wall and a peripheral wall interconnected to a periphery of the bottom wall. The bottom wall includes at least one heat conducting section. The peripheral wall defines a compartment and includes an air inlet in communication with the compartment and an air outlet in communication with the compartment. A stator is received in the compartment of the housing. An impeller is coupled to the stator. A plurality of rows of fins is formed on the at least one heat conducting section of the bottom wall and located in the compartment.

The present invention will become clearer in light of the following detailed description of illustrative embodiments of this invention described in connection with the drawings.

### BRIEF DESCRIPTION OF THE DRAWINGS

The illustrative embodiments may best be described by reference to the accompanying drawings where:

FIG. 1 shows a perspective view of a conventional heat dissipating module.

FIG. 2 shows a perspective view of another conventional heat dissipating module.

FIG. 3 shows a perspective view of a further conventional heat dissipating module.

FIG. 4 shows an exploded, perspective view of a heat dissipating module of a first embodiment according to the preferred teachings of the present invention.

FIG. 5 shows another exploded, perspective view of the heat dissipating module of FIG. 4.

FIG. 6 shows an exploded, perspective view of a heat dissipating module of the first embodiment having a modified housing according to the preferred teachings of the present invention.

FIG. 7 shows an exploded, perspective view of a heat dissipating module of the first embodiment having another modified housing according to the preferred teachings of the present invention.

FIG. 8 shows a top view of the heat dissipating module of the first embodiment according to the preferred teachings of the present invention.

FIG. 9 shows an exploded, perspective view of a heat dissipating module of a second embodiment according to the preferred teachings of the present invention.

FIG. 10 shows a cross sectional view of the heat dissipating module of FIG. 9.

FIG. 11 shows an exploded, perspective view of a heat dissipating module of a third embodiment according to the preferred teachings of the present invention.

FIG. 12 shows a cross sectional view of the heat dissipating module of FIG. 11.

FIG. 13 is a perspective view illustrating use of the heat dissipating module according to the preferred teachings of the present invention with heat pipes.

FIG. 14 is a perspective view illustrating use of the heat dissipating module according to the preferred teachings of the present invention with a plurality of lighting modules.

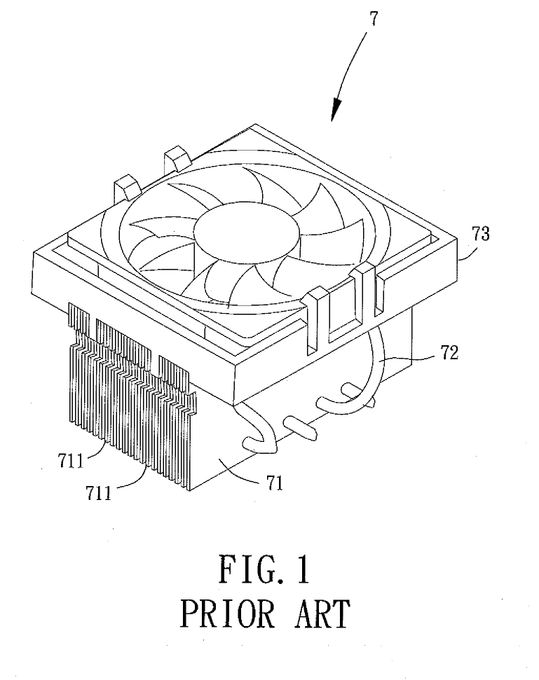

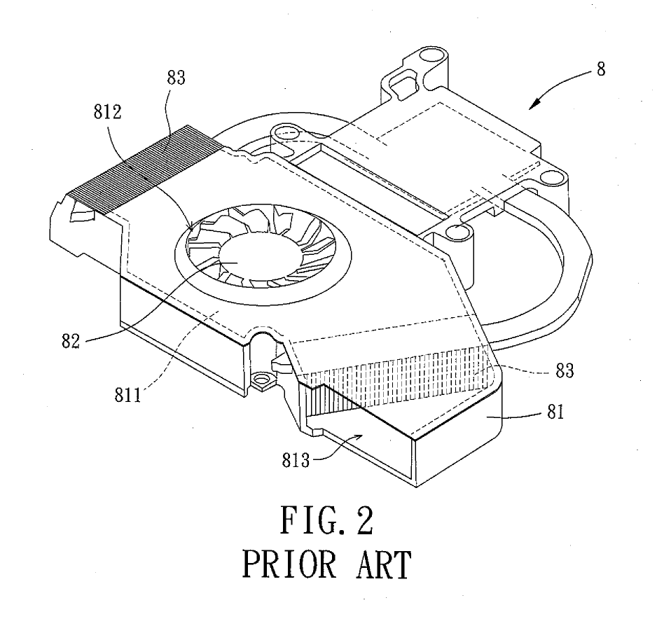

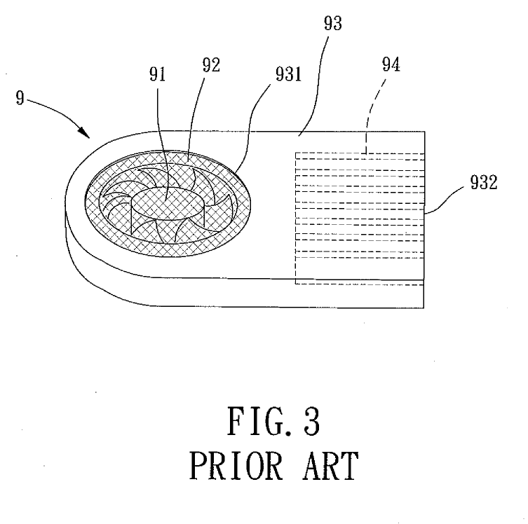

All figures are drawn for ease of explanation of the basic teachings of the present invention only; the extensions of the figures with respect to number, position, relationship, and dimensions of the parts to form the preferred embodiments will be explained or will be within the skill of the art after the following teachings of the present invention have been read and understood. Further, the exact dimensions and dimensional proportions to conform to specific force, weight, strength, and similar requirements will likewise be within the skill of the art after the following teachings of the present invention have been read and understood.

Where used in the various figures of the drawings, the same numerals designate the same or similar parts. Furthermore, when the terms “first”, “second”, “third”, “inner”, “outer”, “end”, “section”, “axial”, “radial”, “circumferential”, “outward”, “height”, and similar terms are used herein, it should be understood that these terms have reference only to the structure shown in the drawings as it would appear to a person viewing the drawings and are utilized only to facilitate describing the invention.

### DETAILED DESCRIPTION OF THE INVENTION

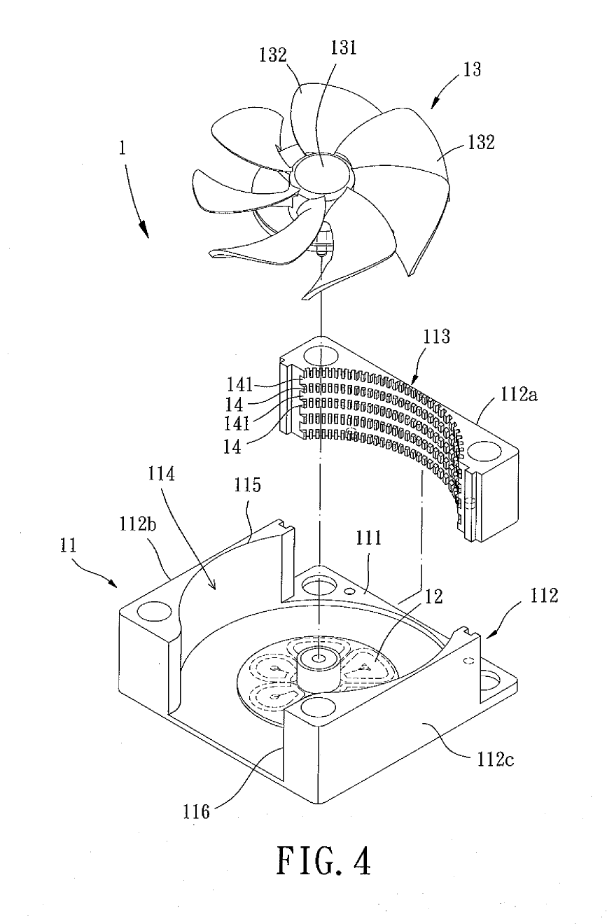

With reference to FIG. 4, a heat dissipating module of a first embodiment according to the preferred teachings of the present invention is designated 1 and includes a housing 11, a stator 12, an impeller 13, and a plurality of rows of fins 14. The housing 11 is preferably a housing of blower type and receives the stator 12 to which the impeller 13 is rotatably mounted. The plurality of rows of fins 14 are provided in predetermined locations of an inner face of the housing 11 for heat conduction purposes. The outer face of the housing 11 opposite to the inner face having the plurality of rows of fins 14 can be coupled to various heat sources of electronic devices to provide enhanced heat dissipation.

The housing 11 includes a bottom wall 111 and a peripheral wall 112 interconnected to a periphery of the bottom wall 111. The peripheral wall 112 including at least one heat conducting section 113 capable of conducting heat. The heat conducting section 113 can be in a specific area or several areas of the peripheral wall 112. The peripheral wall 112 defines a compartment 114 and includes an air inlet 115 in communication with the compartment 114 and an air outlet 116 in communication with the compartment 114.

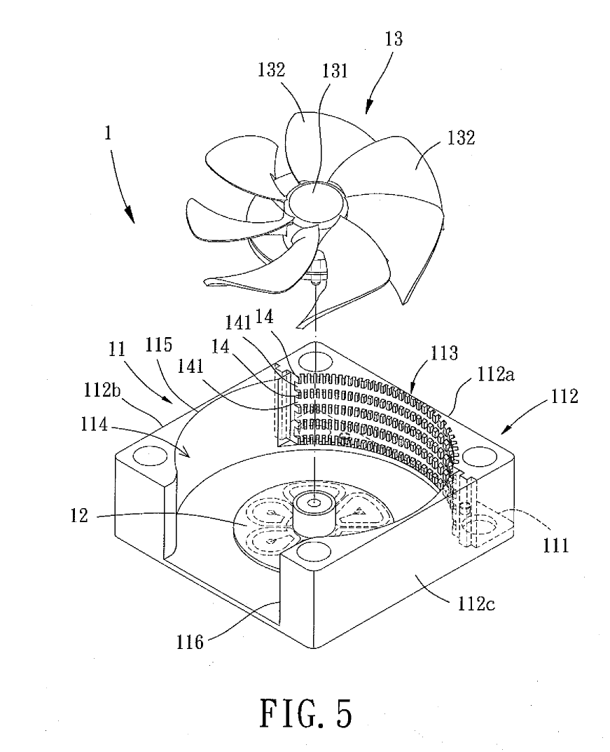

In the preferred form shown in FIGS. 4 and 5, the peripheral wall 112 comprises a plurality of sidewalls 112a, 112b, and 112c. The sidewalls 112a, 112b, and 112c can be integrally formed as a single continuous monolithic piece or detachable from the bottom wall 111. In the preferred form shown in FIGS. 4 and 5, the sidewalls 112b and 112c extend integrally from and perpendicularly to the periphery of the bottom wall 111, and the sidewall 112a is coupled to the sidewalls 112b and 112c and the bottom wall 111 by male/female coupling, welding, and/or bonding. The sidewalls 112a, 112b, and 112c define the compartment 114. Furthermore, the sidewall 112a includes the heat conducting section 113.

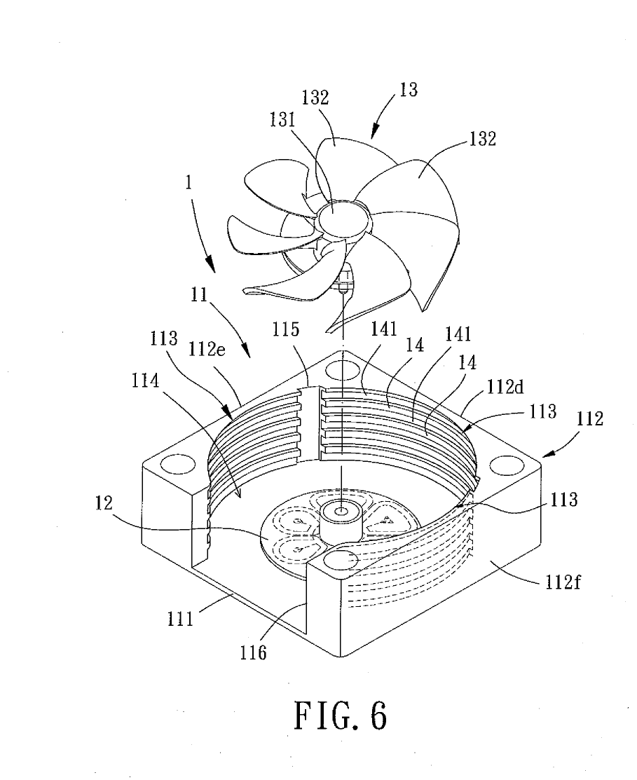

In another preferred form shown in FIG. 6, the peripheral wall 112 comprises a plurality of sidewalls 112d, 112e, and 112f. The sidewalls 112d, 112e, and 112f extend integrally from and perpendicularly to the periphery of the bottom wall 111 and interconnected to each other. The sidewalls 112d, 112e, and 112f define the compartment 114. Furthermore, each sidewall 112d, 112e 112f includes the heat conducting section 113.

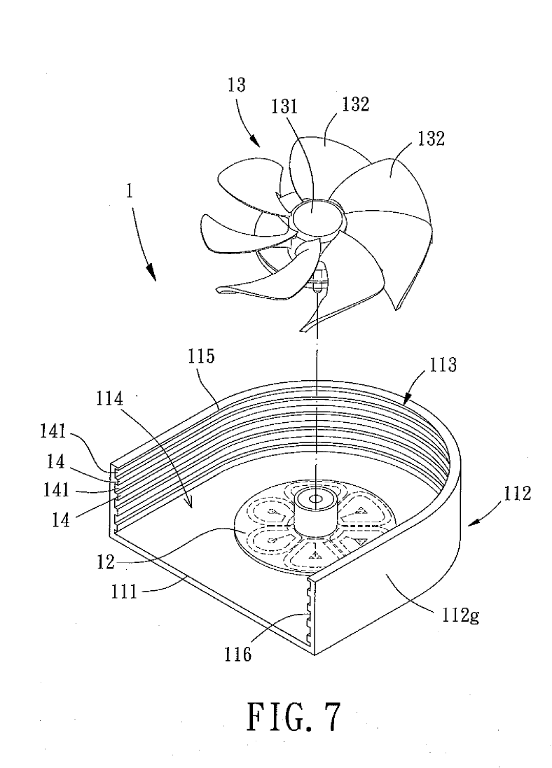

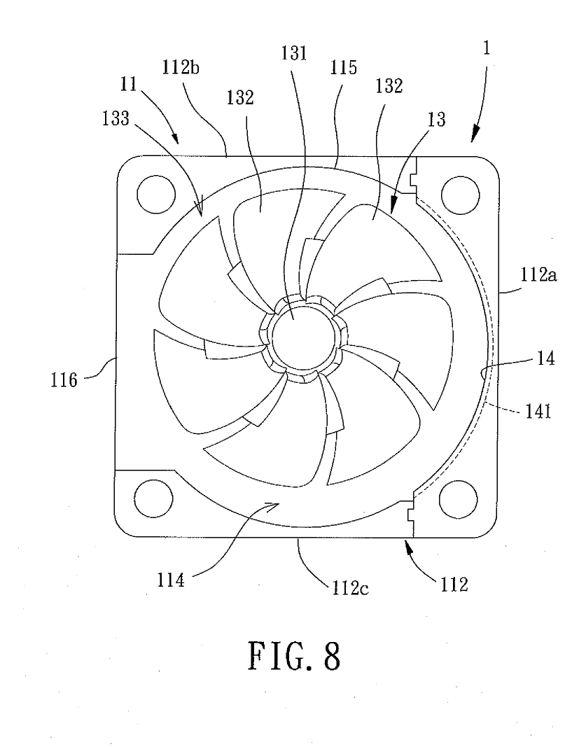

In a further preferred form shown in FIG. 7, the peripheral wall 112 is a wall 112g extends integrally from and perpendicularly to the periphery of the bottom wall 111 and having U-shaped cross sections. The wall 112g defines the compartment 114 and includes the heat conducting section 113.

It can be appreciated that the peripheral wall 112 can have other forms and shapes according to the teachings of the present invention.

The stator 12 is received in the compartment 114 of the housing 11. The stator 12 can include elements such as coils, a drive circuit, a shaft seat, etc. The shaft seat can be coupled to the housing 11. The impeller 13 can be rotatably coupled to and controlled by the stator 12. Thus, the impeller 13 is rotatable relative to the stator 12 about an axis extending perpendicularly to the bottom wall 111 in the preferred forms shown in FIGS. 4-7.

The impeller 13 includes a hub 131 coupled to the stator 12 and a plurality of blades 132. A wind passageway 133 is defined between an outer periphery of the hub 131 and an inner face of the peripheral wall 112 of the housing 11. The blades 132 are formed on the outer periphery of the hub 131 and located in the wind passageway 133. The impeller 13 drives in air current via the air inlet 115 of the housing 11. The blades 132 increases the wind pressure of the air currents accumulated in the wind passageway 133. The air currents are pushed by the wind pressure toward the air outlet 116 and exit the housing 11 to the environment via the air outlet 116.

The plurality of rows of fins 14 is provided on the heat conducting section 113 of the sidewall 112 and located in the compartment 114. Two adjacent rows of fins 14 are spaced in a direction parallel to the axis. A circumferential passageway 141 is formed between two adjacent rows of fins 14 and surrounds the hub 131 and the axis. Thus, when the blades 132 of the impeller 13 pushes the air currents along the wind passageway 133 toward the air outlet 116, the air currents can move along the circumferential passageway 141 and exit the air outlet 116 to the environment without interferences providing enhanced heat dissipating effect with less turbulence.

Specifically, in the preferred form shown in FIGS. 4 and 5, each row of fin 14 is formed on the inner face of the sidewall 112a and includes a plurality of protrusions spaced in a circumferential direction surrounding the axis. In the preferred form shown in FIG. 6, the inner face of each of the sidewalls 112d, 112e, and 112f is formed with a plurality of rows of fins 14 spaced in a direction parallel to the axis. Each of the plurality of rows of fins 14 on each sidewall 112d, 112e, 112f is in the form of a continuous rib. Furthermore, each rib of each sidewall 112d, 112e, 112f is spaced from the ribs on an adjacent sidewall. In the preferred form shown in FIG. 7, the plurality of rows of fins 14 is formed on an inner face of the wall 112g and each in the form of a continuous rib. It can be appreciated that the plurality of rows of fins 14 can be of other forms and shapes according to the teachings of the present invention.

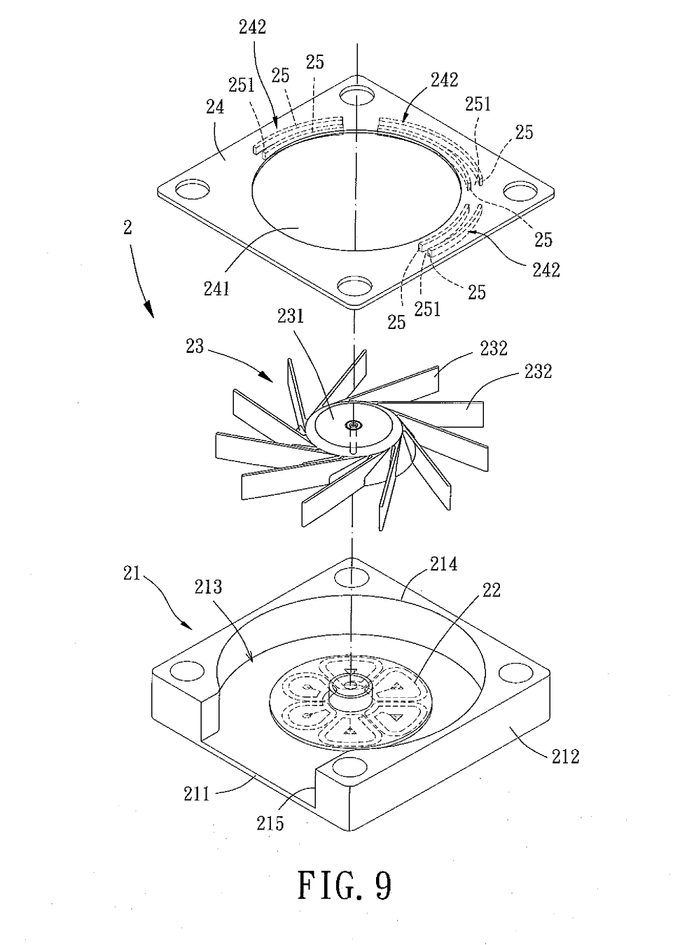

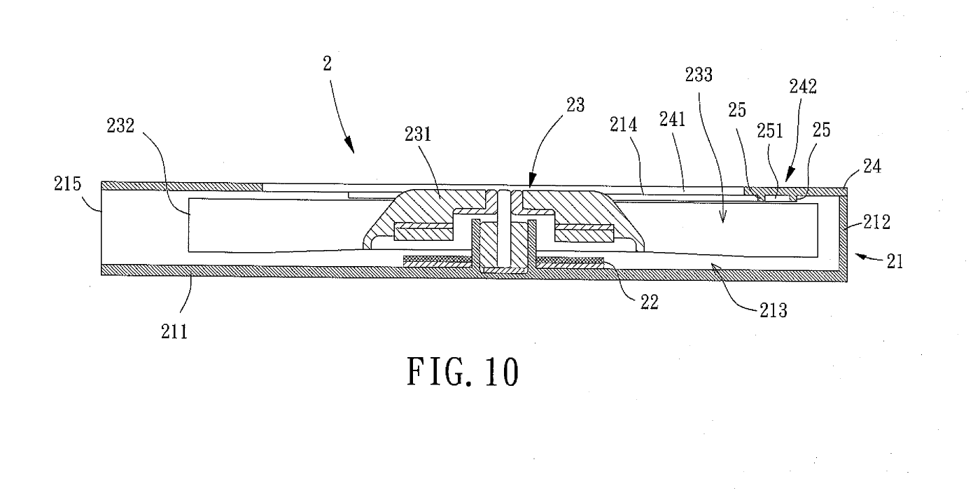

With reference to FIGS. 9 and 10, a heat dissipating module of a second embodiment according to the preferred teachings of the present invention is designated 2 and includes a housing 21, a stator 22, an impeller 23, a lid 24, and a plurality of fins 25.

The housing 21 includes a bottom wall 211 and a peripheral wall 212 interconnected to a periphery of the bottom wall 211 and defining a compartment 213. The peripheral wall 212 further includes an air inlet 214 in communication with the compartment 213 and an air outlet 215 in communication with the compartment 213.

The stator 22 is received in the compartment 213 of the housing 21. The stator 22 can include elements such as coils, a drive circuit, a shaft seat, etc. The impeller 23 can be rotatably coupled to and controlled by the stator 22. Thus, the impeller 23 is rotatable relative to the stator 22 about an axis extending perpendicularly to the bottom wall 211 in the preferred form shown in FIGS. 9 and 10.

The impeller 23 includes a hub 231 coupled to the stator 22 and a plurality of blades 232. A wind passageway 233 is defined between an outer periphery of the hub 231 and an inner face of the peripheral wall 212 of the housing 21. The blades 232 are formed on the outer periphery of the hub 231 and located in the wind passageway 233. The function of the wind passageway 233 is substantially the same as the wind passageway 133 of the first embodiment and therefore not described in detail to avoid redundancy.

The lid 24 is engaged to the air inlet 214 side of the housing 21 and includes an inlet 241 aligned with the air inlet 214. The lid 24 further includes a plurality of heat conducting sections 242 capable of conducting heat. The lid 24 mounted to the housing 21 can guide air currents, increase the wind pressure, and provide heat dissipation. It can be appreciated that the lid 24 can include only one heat conducting section 242.

The plurality of rows of fins 25 is formed on the heat conducting sections 242 of the lid 24, respectively. Furthermore, the plurality of rows of fins 25 is located in the compartment 213. Further, two adjacent rows of fins 25 are spaced in a radial direction perpendicular to the axis. A circumferential passageway 251 is formed between two adjacent rows of fins 25 and surrounds the inlet 241 and the axis and radially outward of the hub 231. The circumferential passageways 251 are preferably located in the wind passageway 233. The function of the circumferential passageways 251 is substantially the same as the circumferential passageway 141 of the first embodiment and therefore not described in detail to avoid redundancy.

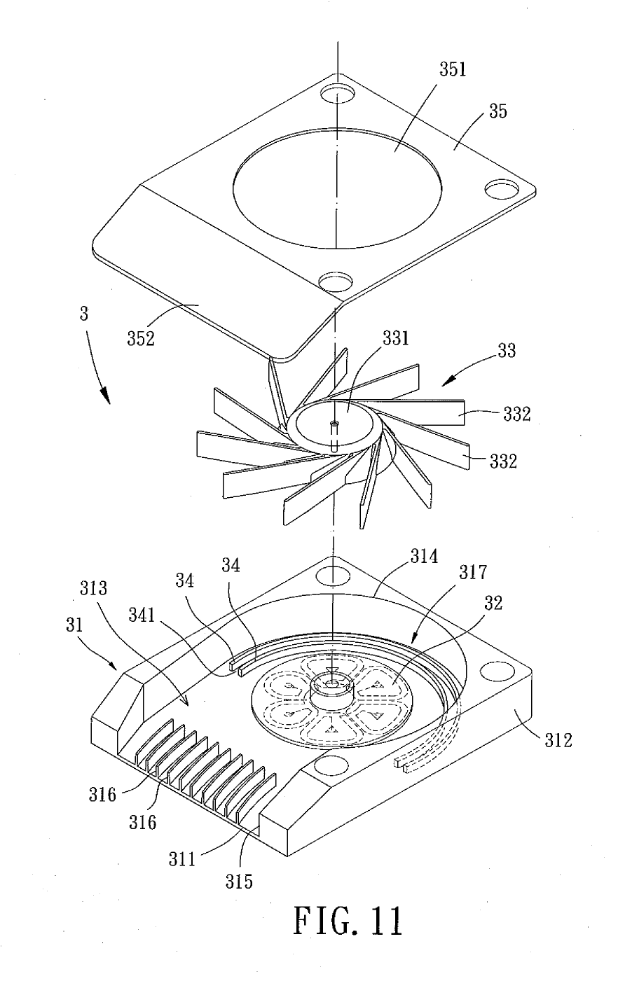

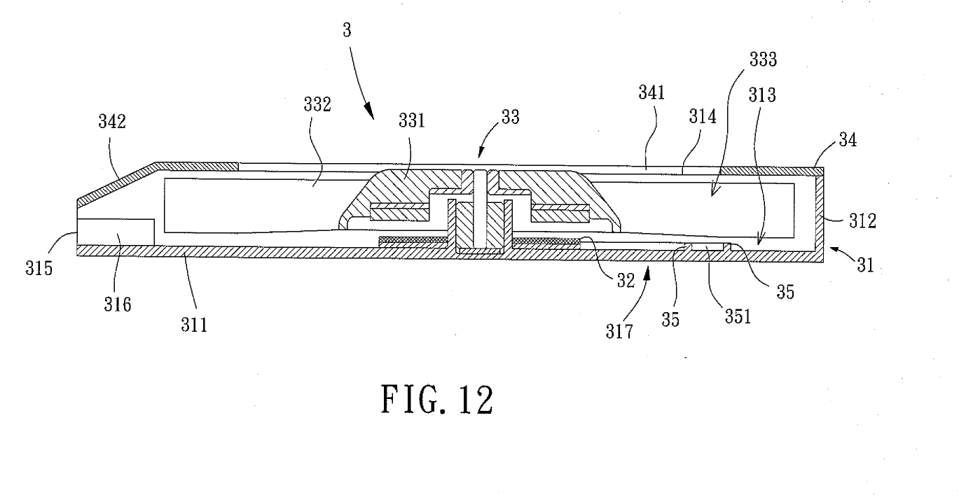

With reference to FIGS. 11 and 12, a heat dissipating module of a third embodiment according to the preferred teachings of the present invention is designated 3 and includes a housing 31, a stator 32, an impeller 33, and a plurality of rows of fins 34.

The housing 31 includes a bottom wall 311 and a peripheral wall 312 interconnected to a periphery of the bottom wall 311 and defining a compartment 313. The peripheral wall 312 further includes an air inlet 314 in communication with the compartment 313 and an air outlet 315 in communication with the compartment 313. A plurality of air deflectors 316 is provided in the air outlet 315 and formed on the bottom wall 311 in the preferred form shown in FIGS. 11 and 12 for guiding the air currents to pass through the air outlet 315. The bottom wall 311 further includes a heat conducting section 317 capable of conducting heat. It can be appreciated that the bottom wall 311 can include several heat conducting sections 317.

The stator 32 is received in the compartment 313 of the housing 31. The stator 32 can include elements such as coils, a drive circuit, a shaft seat, etc. The impeller 33 can be rotatably coupled to and controlled by the stator 32. Thus, the impeller 33 is rotatable relative to the stator 32 about an axis extending perpendicularly to the bottom wall 311 in the preferred form shown in FIGS. 11 and 12.

The impeller 33 includes a hub 331 coupled to the stator 32 and a plurality of blades 332. A wind passageway 333 is defined between an outer periphery of the hub 331 and an inner face of the peripheral wall 312 of the housing 31. The blades 332 are formed on the outer periphery of the hub 331 and located in the wind passageway 333. The function of the wind passageway 333 is substantially the same as the wind passageway 133 of the first embodiment and therefore not described in detail to avoid redundancy.

The plurality of rows of fins 34 is formed on the heat conducting section 317. Furthermore, the plurality of rows of fins 34 is located in the compartment 313. Further, two adjacent rows of fins 34 are spaced in a radial direction perpendicular to the axis. A circumferential passageway 341 is formed between two adjacent rows of fins 34 and surrounds the stator 32 and the axis and radially outward of the hub 331. The circumferential passageway 341 is located in the wind passageway 333. The function of the circumferential passageway 341 is substantially the same as the circumferential passageway 141 of the first embodiment and therefore not described in detail to avoid redundancy.

The heat dissipating module 3 can further include a lid 35 engaged to a side of the housing 31 where the air inlet 314 is disposed, and including an inlet 351 aligned with the air inlet 314. The lid 35 further includes a deflector 352 formed on an edge of the lid 35 adjacent the air outlet 315. The deflector 352 extends from the edge of the lid 35 towards but spaced from the bottom wall 311. By such an arrangement, the air currents driven by the blades 332 to flow along the wind passageway 333 can be further guided to the environment by the deflector 352 after passing through the air outlet 315, providing enhanced wind pressure increasing effect.

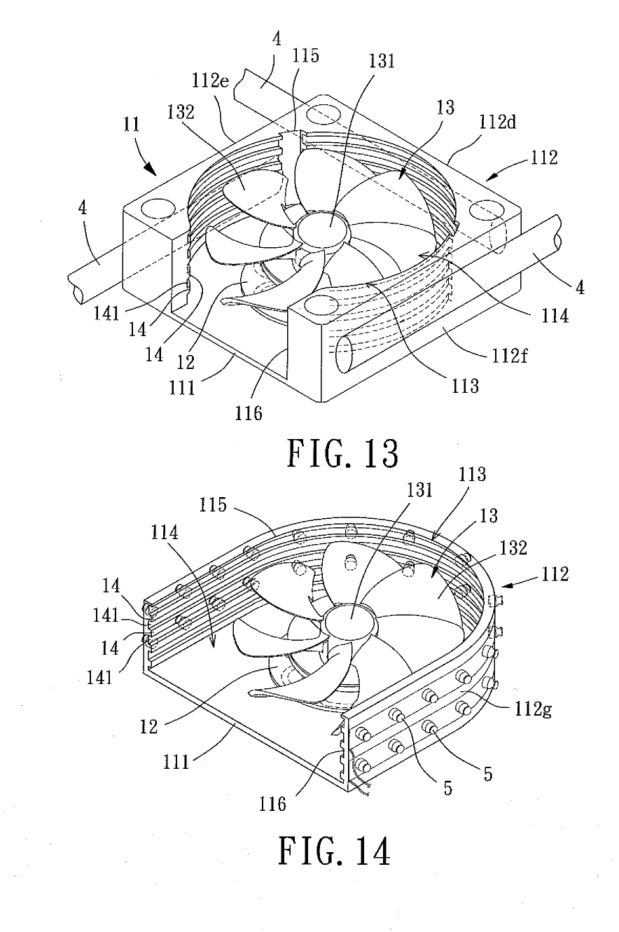

In use, the heat dissipating module 1, 2, 3 can be coupled with various heat sources at the same time. In an example of use of the heat dissipating module 1 shown in FIG. 6 with a plurality of heat pipes 4 shown in FIG. 13, each heat pipe 4 is in contact with an outer face of one of the sidewalls 112d, 112e, and 112f. The heat pipes 4 are connected to various heat sources such as central processing units, main boards, electronic chips, and/or lighting modules. In another example of use of the heat dissipating module 1 shown in FIG. 7, heat sources such as a plurality of lighting modules 5 are directly mounted to the outer face of the wall 112g of the heat conducting section 113 of the peripheral wall 112. It can be appreciated that various heat sources can be directly coupled to the heat conducting section 113 shown in FIG. 5, or to the heat conducting section 242 of the lid 24 shown in FIGS. 9 and 10, or to the heat conducting section 317 of the bottom wall 311 shown in FIGS. 11 and 12. Thus, the heat generated by the various heat sources can be conducted to the fins 14, 25, 34 via the heat conducting section 113, 242, 317. Furthermore, the impeller 13, 23, 33 drives air currents to pass through the fins 14, 25, 34 and exit the air outlet 116, 215, 315 to the environment. When coupled with various heat sources, the heat dissipating modules 1, 2, and 3 having higher heat dissipating efficiency can be selected to avoid adverse affect to the heat dissipating effect.

The heat dissipating module 1, 2, 3 according to the preferred teachings of the present invention can include at least one heat conducting section 113, 242, 317 in a predetermined location of the housing 11, 21, 31, such as on the peripheral wall 112, the lid 24 (which can be deemed as a part of the housing 21), or the bottom wall 311. Furthermore, a plurality of rows of fins 14, 25, 34 is formed on the inner face of the at least one heat conducting section 113, 242, 317, and the outer face of the at least one heat conducting section 113, 242, 317 can be engaged with various heat sources. It can be appreciated that at least one heat conducting section 113, 242, 317 can be formed on more than one of the peripheral wall 112, the lid 24, and the bottom wall 311. As an example, at least one heat conducting section is formed on each of the peripheral wall of the housing and the lid. In another example, at least one heat conducting section is formed on each of the peripheral wall and the bottom wall of the housing. In a further example, at least one heat conducting section is formed on each of the peripheral wall, the lid, and the bottom wall of the housing.

The heat dissipating module 1, 2, 3 according to the preferred teachings of the present invention can easily be installed in an electronic device by incorporating the fins 14, 25, 34 in the housing 11, 21, 31 so that the volume and axial length of the heat dissipating module 1, 2, 3 are respectively the volume and axial length of the housing 11, 21, 31. Compared to the conventional heat dissipating modules 7, 8, and 9, the heat dissipating module 1, 2, 3 can more effectively reduce the volume and axial height to allow easy installation in the electronic device and to allow easy coupling with the heat sources of the electronic device without occupying a considerable space in the electronic device. Furthermore, by providing the plurality of rows of fins 14, 25, 34 on the at least one heat conducting section 113, 242, 317 of the housing 11, 21, 31, the heat dissipating module 1, 2, 3 according to the preferred teachings of the present invention can be coupled to various heat sources at the same time by the outer face of the at least one heat conducting section 113, 242, 317, providing enhanced utility. Furthermore, inconvenient installation of the conventional heat dissipating modules 7, 8, and 9 does not occur in the heat dissipating module 1, 2, 3 according to the preferred teachings of the present invention by incorporating the fins 14, 25, 34 in the housing 11, 21, 31. Thus, the heat dissipating module 1, 2, 3 according to the preferred teachings of the present invention can easily be installed in an electronic device without complicated assembly. Further, the heat dissipating module 1, 2, 3 according to the preferred teachings of the present invention has fewer elements and, thus a simple structure, reducing structural complexity, reducing manufacturing costs, and allowing compact and miniature designs. Further, when the heat dissipating module 1, 2, 3 according to the preferred teachings of the present invention is coupled to various heat sources, the heat generated by the heat sources is conducted by the heat conducting section 113, 242, 317 to the fins 14, 25, 34. Furthermore, the impeller 13, 23, 33 drives air currents to flow through the fins 14, 25, 34, prolonging the contact time between the air currents and the fins 14, 25, 34 and, thus, enhancing the heat conduction effect while decreasing turbulence. The heat dissipating effect is, thus, enhanced.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

What is claimed is:

1. A heat dissipating module comprising:
a housing including a bottom wall and a peripheral wall interconnected to a periphery of the bottom wall, with the peripheral wall including at least one first heat conducting section, with the peripheral wall defining a compartment, with the peripheral wall further including an air inlet in communication with the compartment and an air outlet in communication with the compartment;
a stator received in the compartment of the housing;
an impeller coupled to the stator; and
a plurality of rows of first fins formed on said at least one first heat conducting section of the peripheral wall and located in the compartment.

2. The heat dissipating module as claimed in claim 1, further comprising: a lid coupled to a side of the housing where the air inlet is disposed, with the lid including an inlet aligned with the air inlet of the housing, with the lid further including at least one second heat conducting section, and with a plurality of rows of second fins formed on said at least one second heat conducting section of the lid and located in the compartment.

3. The heat dissipating module as claimed in claim 1, with the bottom wall including at least one second heat conducting section, and with a plurality of rows of second fins formed on said at least one second heat conducting section of the bottom wall and located in the compartment.

4. The heat dissipating module as claimed in claim 2, with the bottom wall including at least one third heat conducting section, and with a plurality of rows of third fins formed on said at least one third heat conducting section of the bottom wall and located in the compartment.

5. The heat dissipating module as claimed in claim 1, with the impeller including a hub coupled to the stator and rotatable about an axis, with the hub having an outer periphery, with the impeller further including a plurality of blades formed on the outer periphery of the hub, with a wind passageway formed between the outer periphery of the hub and an inner face of the peripheral wall of the housing, with the plurality of blades located in the wind passageway, and with a circumferential passageway formed between two adjacent rows of fins and surrounding the hub and the axis.

6. The heat dissipating module as claimed in claim 5, with the circumferential passageway located in the wind passageway.

7. The heat dissipating module as claimed in claim 1, with the peripheral wall comprising a plurality of sidewalls together defining the compartment, and with one of the plurality of sidewalls including said at least one first heat conducting section of the peripheral wall.

8. The heat dissipating module as claimed in claim 1, with the peripheral wall comprising a plurality of sidewalls together defining the compartment, and with each of the plurality of sidewalls including said at least one first heat conducting section of the peripheral wall.

9. The heat dissipating module as claimed in claim 1, with the peripheral wall including a wall having U-shaped cross sections and defining the compartment, and with the wall including said at least one first heat conducting section of the peripheral wall.

10. A heat dissipating module comprising:
a housing including a bottom wall and a peripheral wall interconnected to a periphery of the bottom wall, with the peripheral wall defining a compartment, with the peripheral wall including an air inlet in communication with the compartment and an air outlet in communication with the compartment;
a stator received in the compartment of the housing;
an impeller coupled to the stator;
a lid coupled to the air inlet side of the housing, with the lid including an inlet aligned with the air inlet of the housing, with the lid further including at least one heat conducting section; and
a plurality of rows of fins formed on said at least one heat conducting section of the lid and located in the compartment.

11. The heat dissipating module as claimed in claim 10, with the impeller including a hub coupled to the stator and rotatable about an axis, with the hub having an outer periphery, with the impeller further including a plurality of blades formed on the outer periphery of the hub, with a wind passageway formed between the outer periphery of the hub and an inner face of the peripheral wall of the housing, with the plurality of blades located in the wind passageway, and with a circumferential passageway formed between two adjacent rows of fins and surrounding the inlet of the lid and the axis and radially outward of the hub.

12. The heat dissipating module as claimed in claim 11, with the circumferential passageway located in the wind passageway.

13. A heat dissipating module comprising:
a housing including a bottom wall and a peripheral wall interconnected to a periphery of the bottom wall, with the bottom wall including at least one heat conducting section, with the peripheral wall defining a compartment, with the peripheral wall including an air inlet in communication with the compartment and an air outlet in communication with the compartment;
a stator received in the compartment of the housing;
an impeller coupled to the stator; and
a plurality of rows of fins formed on said at least one heat conducting section of the bottom wall and located in the compartment.

14. The heat dissipating module as claimed in claim 13, with the impeller including a hub coupled to the stator and rotatable about an axis, with the hub having an outer periphery, with the impeller further including a plurality of blades formed on the outer periphery of the hub, with a wind passageway formed between the outer periphery of the hub and an inner face of the peripheral wall of the housing, with the plurality of blades located in the wind passageway, and with a circumferential passageway formed between two adjacent rows of fins and surrounding the stator and the axis and radially outward of the hub.

15. The heat dissipating module as claimed in claim 14, with the circumferential passageway located in the wind passageway.

16. The heat dissipating module as claimed in claim 13, further comprising: a lid coupled to the air inlet side of the housing, with the lid including an inlet aligned with the air inlet of the housing, with the lid further including a deflector formed on an edge of the lid adjacent the air outlet.

17. The heat dissipating module as claimed in claim 16, with the deflector extending from the edge of the lid towards but spaced from the bottom wall.

18. The heat dissipating module as claimed in claim 13, with the housing further including a plurality of air deflectors formed in the air outlet.
